(19) United States
(12) Patent Application Publication
(10) Pub. No.: US 2010/0288337 A1
(43) Pub. Date: Nov. 18, 2010

(54) SOLAR PANEL ASSEMBLY

(76) Inventor: Nathan Rizzo, Wheatfield, NY (US)

Correspondence Address: Jaekle Fleischmann & Mugel, LLP, 12 Fountain Plaza, Buffalo, NY, 14202-2292, US

(21) Appl. No.: 12/779,256

(22) Filed: May 13, 2010

Related U.S. Application Data
(60) Provisional application No. 61/178,029, filed on May 13, 2009.

(51) Int. Cl. H01L 31/048

(52) U.S. Cl. 136/251

(57) ABSTRACT

The present invention includes a solar panel mounting system. The system comprises a first row of a plurality of generally horizontal first bases. The system also includes a second row of a plurality of generally horizontal second bases and a third row of a plurality of generally horizontal third bases. Each of the first bases, second bases and third bases have a short pair of upwardly extending legs affixed to one side of the base and a long pair of upwardly extending legs affixed to the other side. Each of the first bases, second bases and third bases are generally configured to be stacked on top of other of the first bases, second bases and third bases, such that the each of the bases abut against the other of the bases and the respective short pair of legs and the long pair legs of each of the bases fit offset from and adjacent to the respective short pair and long pair of the other of the bases.

### CROSS-REFERENCE TO RELATED APPLICATIONS

This application claims the benefit of U.S. Provisional Application No. 61/178,029 filed May 13, 2009, which application is incorporated by reference into this application in its entirety.

### BACKGROUND

Solar energy provides the opportunity to generate electricity without consumption of fossil fuels and is considered clean technology. In recent years, the development of technology for solar thermal systems and photovoltaic systems has improved the overall viability of solar energy. Thus, the demand for solar energy has increased.

Efficiency of solar panel systems can be improved by effective installation. The direction of the solar panels relative to the sun, the angle of the solar panels relative to the horizon, the density of solar panels in a given area, as well as position of solar panels relative to other panels can have a positive or negative effect on performance of the solar powered system. Such considerations are of great importance when assembling a solar panel system on a flat roof with limited area. The ability to assemble with one additional row of solar panels without causing overlap of the solar panels in sunlight or compromising optimal positioning would be a great advantage. Moreover, it would be advantageous if panels and their support structures could be assembled to provide easy installation, reduced shipping cost and function effectively.

The present invention addresses these and other needs.

### SUMMARY OF THE INVENTION

The present invention is a solar panel mounting system that eliminates the last row of support bases by positioning the base beneath the panel. This potentially may provide room for an additional row of panels. Additionally, the bases are configured to be stackable for inexpensive storage and distribution.

The mounting system comprises a first row of a plurality of generally horizontal first bases, a second row of a plurality of generally horizontal second bases, and a third row of a plurality of generally horizontal third bases. Each of the first bases, second bases and third bases have a short pair of upwardly extending legs affixed to one side of the base and a long pair of upwardly extending legs affixed to the other side. Each of the first bases, second bases and third bases are generally configured to be stacked on top of other of the first bases, second bases and third bases. When stacked, each of the bases abuts against the other of the bases and fit between the legs of the other of the bases. The respective short pair of legs and the long pair legs of each of the bases fit offset from and adjacent to the respective short pair and long pair of the other of the bases.

One row of frames is supportably affixed to solar panels. The first row of frames have a front side and a back side, wherein the front side of the one row of frames is affixed to and supported by the short pair of legs of the first row of a plurality of generally horizontal first bases. Furthermore, the back side of the one row of frames is affixed to and supported by the long pairs of the second row of second bases. Additionally, a back row of frames are supportably affixed to solar panels. The back row of frames have a front side and a back side, wherein the front side of the back row of frames is affixed to and supported by the short pair of legs of the second row of a plurality of generally horizontal second bases. Furthermore, the back side of the back row of frames is affixed to and supported by the long pair of legs of the third row of a plurality of generally horizontal second bases. The third base is positioned directly beneath the back row of frames.

### BRIEF DESCRIPTION OF THE DRAWINGS

FIG. 1 is a cross sectional view of the solar panel mounting system of one embodiment of the present invention.

FIG. 2 is a front view of the solar panel mounting system of one embodiment of the present invention.

### DETAILED DESCRIPTION OF THE INVENTION

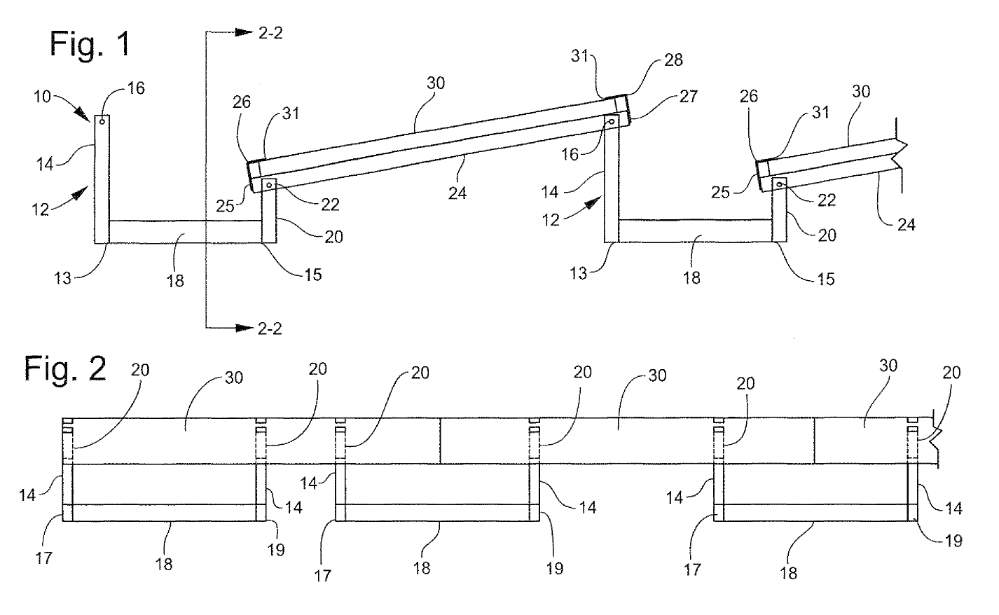

The present invention is a solar panel mounting system 10. One example is illustrated in FIG. 1 with continued reference to FIG. 2. The solar panel mounting system 10 comprises a plurality of base supports 12 that are arranged to support a plurality of panel frames 24. The base supports 12 have a base 18 that is affixed to a pair of long arms 14 and a pair of short arms 20. The pair of long arms 14 and pair of short arms 20 extend vertically from the generally horizontal base 18. A fixture site 16 is located at the top of the long arm 14. A similar fixture site 22 is located at the top of the short arm 20. The fixture sites 22 and 16, in one embodiment are holes that receive a pin or bolt. They can be any connector that is capable of attaching two portions of a frame together.

The fixture sites 16 and 22 connect the panel frame 24 to the base supports 12. The panel frame 24 has along the front end 25 and a back end 27. The panel frame is configured to be affixed to the solar panel 30. As illustrated in FIG. 1, U-channels 26 and 28 are formed in the frame to receive the solar panel 30 under a lip 31.

The base 18 of one embodiment has a length, a width and a height. The length is greater than the width. The base has a front side 13 and a back side 15 on respective sides of the width of the base. The base has a first end 17 and a second end 19 on the respective sides of the length of the base. The front side 13 generally correspond to the side that has a long legs affixed thereto and the back side 13 generally corresponds to the side that has short legs affixed thereto. The first end 15 and the second end of the base are arbitrary designations and can refer to either ends as oriented along the length of the base 18.

In one embodiment, the base 18 is an angle basket or tray that receives into the angle basket a weight for anchoring the solar panel system to a generally flat roof. The weight is typically a metal weight such as a cast iron weight or a cement block. The base has a height that is a minimum of 1 inch and a maximum of 4 inches and preferably is about 2.5 inches high. The base has a width that is a minimum of about 8 inches and a maximum of about 3 feet. Preferably the base is about 1.5 feet wide. The length of the base is a minimum of about 1 foot and a maximum of about 3 feet. Preferably the length of the base is about 2.5 feet. Preferably, the length of the base 18 is aligned with the length of the solar panels 30.

On the front end of the base 18 is a pair of long legs 14. As illustrated from the front side view of FIG. 2, the long legs 14 are attached to the front side of the base towards opposite ends of the base 18. It is important to accomplish stackability that that the arms are attached to the outside ends 13 and 15 of the base 18. The back side 15 of the base 18 has affixed thereto short legs that are aligned with and opposite the long legs 14. The short legs 20 are vertically oriented and affixed to the back side of the base at either end in one embodiment. The long legs 14 and the short legs 20 are affixed to the respective front side 13 and back side 15 such that another base 18 can be passed between the long legs and the short legs to stack such that the base that stacks on top abuts against the base on the bottom.

Although not shown in stacked formation, the legs 14 and 20 of a base 18 that is stacked on top of another base 18 can be positioned adjacent to but offset from the legs of the said another base that is oriented below. In this regard, the bases can be stacked efficiently for storage and shipping.

The solar panel frame 24 is attached to the attachment points 16 and 22 of a long leg of one base 18 at the back side 27 of the solar panel frame 24 and a short leg 20 of another base 18 at the front side 25 of the solar panel 24. In one embodiment, the long legs 14 and short legs 20 cooperate to position the solar panel at an angle that is a minimum of 5 degrees and a maximum of 40 degrees from horizontal. Preferably the angle is a minimum of 5 degrees and a maximum of 30 degrees. In one preferred embodiment the angle is preferably about 10 degrees from horizontal or 100 degrees from vertical. While a higher angle may intercept the sunlight at a more efficient angle, the panels at a higher angle tend to block the sunlight of the panel behind the previous panel. Thus, a lower angle facilitates placing the panels with as little space in between. Accordingly, in one embodiment, the long leg is made of a 1½ inch square metal tube or bar and has a length of about 1′ 1 7/16″. The short legs are, likewise, made of 1½ inch tube or bar and have a length of about 6⅞″.

The panels can be arranged in rows aligned along length of the panels 30 and bases 18 as illustrated in FIG. 2. A base that supports a panel frame 24 on one extremity of a row of panels is an end base. The frame it supports is an end frame and the solar panel that it supports is an end panel. The end base is affixed to the end panel frame such panel so that the end base is oriented beneath the respective end panel. Every other base that is not located on the end is attached to the respective ends of the base so that the panels fit as closely together as possible.

The panels 22 are arranged from front to back as shown in FIG. 1. The first row of panels is supported by the short legs of a row of bases. The bases are oriented in front of the first row of panels. In another embodiment the long legs are removed from the first row of bases and the bases are reversed so that the bases are oriented beneath the first row of panels. The back side of the panel is supported by a long leg from a second row of bases which in turn support a second row of panels by the long legs of the short legs of the second row of bases. This pattern continues until the last row of panels is supported by long legs of a last row of bases. However, the orientation of the bases is turned so that the base is directly beneath the last solar panel.

1. A solar panel mounting system, comprising:
a first row of a plurality of generally horizontal first bases;
a second row of a plurality of generally horizontal second bases;
a third row of a plurality of generally horizontal third bases;
wherein each of the first bases, second bases and third bases have a short pair of upwardly extending legs affixed to one side of the base and a long pair of upwardly extending legs affixed to the other side, and wherein each of the first bases, second bases and third bases are generally configured to be stacked on top of other of the first bases, second bases and third bases, such that the each of the bases abut against the other of the bases and the respective short pair of legs and the long pair legs of each of the bases fit offset from and adjacent to the respective short pair and long pair of the other of the bases;
a one row of frames supportably affixed to solar panels, the first row of frames have a front side and a back side; wherein the front side of the one row of frames is affixed to and supported by the short pair of legs of the first row of a plurality of generally horizontal first bases, and wherein the back side of the one row of frames is affixed to and supported by the long pairs of the second row of second bases;
a back row of frames supportably affixed to solar panels, the back row of frames have a front side and a back side; wherein the front side of the back row of frames is affixed to and supported by the short pair of legs of the second row of a plurality of generally horizontal second bases, and wherein the back side of the back row of frames is affixed to and supported by the long pair of legs of the third row of a plurality of generally horizontal second bases, wherein the third base is positioned directly beneath the back row of frames.
